(19) United States
(12) Patent Application Publication
(10) Pub. No.: US 2025/0391780 A1
(43) Pub. Date: Dec. 25, 2025

(54) INTERPOSER FOR SEMICONDUCTOR DEVICES

(71) Applicant: Adeia Semiconductor Bonding Technologies Inc., San Jose, CA (US)

(72) Inventors: Belgacem HABA, Saratoga, CA (US); Rajesh KATKAR, Milpitas, CA (US)

(21) Appl. No.: 18/926,994

(22) Filed: Oct. 25, 2024

Related U.S. Application Data
(60) Provisional application No. 63/662,362, filed on Jun. 20, 2024.

(51) Int. Cl. H01L 23/538; H01L 23/00; H01L 25/16

(52) U.S. Cl. CPC H01L 23/5386; H01L 24/08; H01L 24/16; H01L 25/16; H01L 2224/08225; H01L 2224/16225

(57) ABSTRACT

A structure is disclosed. The structure can include a first processor die and an interposer. The first processor die comprises a first processor core and a second processor core. The first processor die is disposed above and bonded to the interposer. The interposer comprises a first plurality of conductors electrically connecting the first processor core and the second processor core. The first processor core and the second processor core communicate with each other through the first plurality of conductors.

### CROSS-REFERENCE TO RELATED APPLICATIONS

This application claims priority to U.S. Provisional Patent Application No. 63/662,362 titled “INTERPOSER FOR SEMICONDUCTOR DEVICES” and filed on Jun. 20, 2024, the disclosure of which is hereby incorporated by reference in its entirety and for all purposes.

### BACKGROUND

### Field

This disclosure relates to semiconductor device structures and methods. In particular, some embodiments are directed to methods and structures for connecting semiconductor dies.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Interposers provide a viable solution for connecting semiconductor dies in semiconductor packages. However, implementations of interposers usually result in underutilization of available spaces. For example, less than five to ten percent of interposer area may be utilized to its full wiring capacity, especially for larger interposers used in certain high computational complexity applications. Accordingly, there remains a continuing need for improved interposers for semiconductor devices.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates a side schematic sectional view of a conventional bonded structure including an interposer.

FIG. 1B illustrates a side schematic sectional view of a conventional bonded structure including interconnect bridges.

FIG. 1C illustrates a side schematic sectional view of a portion of a conventional bonded structure including an interposer.

FIG. 1D illustrates a side schematic sectional view of a portion of a conventional bonded structure including layers in a processor die.

FIG. 2 illustrates a side schematic sectional view of a bonded structure including an interposer according to some embodiments.

FIG. 3 illustrates a side schematic sectional view of a bonded structure including layers in a processor die according to some embodiments.

FIGS. 4A and 4B schematically illustrate cross-sectional side views of two elements prior to and after, respectively, a process for forming a directly bonded structure, and more particularly a hybrid bonded structure, according to some embodiments.

### SUMMARY

The systems, methods, and devices described herein each have several aspects, no single one of which is solely responsible for its desirable attributes. Without limiting the scope of this disclosure, several non-limiting features will now be described briefly.

In some aspects, the techniques described herein relate to a structure including: a processor die including a first processor core and a first circuit block; a semiconductor die; and a connecting element hybrid bonded to the processor die and electrically connecting at least the processor die and the semiconductor die, the connecting element including a first plurality of conductors electrically connecting the first processor core and the first circuit block, wherein the first processor core and the first circuit block communicate with each other through the first plurality of conductors.

In some aspects, the techniques described herein relate to a structure, wherein the first circuit block includes a second processor core or a first cache.

In some aspects, the techniques described herein relate to a structure, wherein the processor die does not include a global redistribution layer (RDL) that is used to connect processor cores or circuit blocks of the processor die.

In some aspects, the techniques described herein relate to a structure, wherein the processor die includes a second plurality of conductors electrically connecting at least a first block of the first processor core and a second block of the first processor core.

In some aspects, the techniques described herein relate to a structure, wherein the processor die includes a third plurality of conductors electrically connecting at least a first transistor of the first block of the first processor core and a second transistor of the first block of the first processor core.

In some aspects, the techniques described herein relate to a structure, wherein the second plurality of conductors and the third plurality of conductors facilitate partial functionality associated with the processor die, and wherein the first plurality of conductors, the second plurality of conductors, and the third plurality of conductors facilitate complete functionality associated with the processor die.

In some aspects, the techniques described herein relate to a structure, wherein the processor die includes one or more intermediate layers, wherein the second plurality of conductors are embedded in the one or more intermediate layers, and wherein a thickness of the one or more intermediate layers is less than 0.5 μm.

In some aspects, the techniques described herein relate to a structure, wherein the processor die includes one or more local layers, and wherein the third plurality of conductors are embedded in the one or more local layers.

In some aspects, the techniques described herein relate to a structure, wherein the first plurality of conductors form, at least in part, one or more global layers for the processor die, and wherein a thickness of the one or more global layers is between 0.5 μm to 5 μm.

In some aspects, the techniques described herein relate to a structure, wherein the semiconductor die includes another processor die or a stack of memory dies.

In some aspects, the techniques described herein relate to a structure, wherein the connecting element includes one or more through substrate vias (TSVs).

In some aspects, the techniques described herein relate to a structure, further including a substrate, wherein the one or more through substrate vias (TSVs) electrically connect the substrate and the connecting element.

In some aspects, the techniques described herein relate to a structure, wherein the processor die and the semiconductor die are disposed on a first side of the connecting element.

In some aspects, the techniques described herein relate to a structure, further including one or more capacitors, wherein the one or more capacitors are disposed on a second side of the connecting element that is opposite to the first side of the connecting element.

In some aspects, the techniques described herein relate to a structure, wherein the processor die and the semiconductor die are laterally spaced from each other.

In some aspects, the techniques described herein relate to a structure, wherein the processor die includes at least one of a system on a chip (SOC), a central processing unit (CPU), and a graphics processing unit (GPU).

In some aspects, the techniques described herein relate to a structure, wherein the processor die is hybrid bonded to the connecting element.

In some aspects, the techniques described herein relate to a structure, wherein the semiconductor die includes a memory unit that is hybrid bonded to the connecting element or thermally compression bonded (TCB) to attach to the connecting element.

In some aspects, the techniques described herein relate to a structure, wherein the connecting element is an interposer, the interposer including one or more global redistribution layers (RDLs).

In some aspects, the techniques described herein relate to a structure, wherein the connecting element includes one or more capacitors embedded in the one or more global redistribution layers (RDLs).

In some aspects, the techniques described herein relate to a structure including: a first processor die including a first processor core and a first block; a semiconductor die; and a connecting element hybrid bonded to the first processor die and electrically connecting at least the first processor die and the semiconductor die, the connecting element including a first plurality of conductors electrically connecting the first processor core and the first block, wherein the first processor core and the first block communicate with each other through the first plurality of conductors.

In some aspects, the techniques described herein relate to a structure, wherein the semiconductor die includes a second processor die.

In some aspects, the techniques described herein relate to a structure, wherein the first block includes a second processor core or a first cache.

In some aspects, the techniques described herein relate to a structure including: a first processor die including a first processor core and a second processor core, the first processor die disposed above and hybrid bonded to an interposer; and the interposer including a first plurality of conductors electrically connecting the first processor core and the second processor core, wherein the first processor core and the second processor core communicate with each other through the first plurality of conductors.

In some aspects, the techniques described herein relate to a structure, further including a substrate, wherein the interposer includes one or more through substrate vias (TSVs) that electrically connect the interposer to the substrate.

In some aspects, the techniques described herein relate to a structure, wherein the first processor die includes at least one of a system on a chip (SOC), a central processing unit (CPU), and a graphics processing unit (GPU).

In some aspects, the techniques described herein relate to a structure including: an interposer having a global interconnect layer region; a processor die including a plurality of processor cores and a memory cache, the processor die hybrid bonded to the interposer, the processor die including first interconnect layers and second interconnect layers; and a semiconductor die bonded to the interposer and electrically connected to the processor die through the interposer, wherein the global interconnect layer region of the interposer, the first interconnect layers of the processor die, and the second interconnect layers of the processor die facilitate complete functionality of the processor die.

In some aspects, the techniques described herein relate to a structure, wherein a first processor core of the plurality of processor cores and a second processor core of the plurality of processor cores communicate with each other through the global interconnect layer region of the interposer.

In some aspects, the techniques described herein relate to a structure, further including one or more capacitors, wherein the processor die and the semiconductor die are disposed on a first side of the interposer, and wherein the one or more capacitors are disposed on a second side of the interposer that is opposite to the first side of the interposer.

In some aspects, the techniques described herein relate to a structure, wherein the second interconnect layers electrically connect at least a first block of a first processor core of the plurality of processor cores and a second block of the first processor core of the plurality of processor cores.

In some aspects, the techniques described herein relate to a structure, wherein the first interconnect layers electrically connect at least a first transistor of the first block of the first processor core of the plurality of processor cores and second transistor of the first block of the first processor core of the plurality of processor cores.

In some aspects, the techniques described herein relate to a structure, wherein the processor die includes a second plurality of conductors electrically connecting at least a first block of the first processor core and a second block of the first processor core, wherein the second plurality of conductors are hybrid bonded to the first plurality of conductors.

In some aspects, the techniques described herein relate to a structure, wherein a hybrid bonding pitch for hybrid bonding the first plurality of conductors and the second plurality of conductors is between 0.2 μm to 5 μm.

Various combinations of the above and below recited features, embodiments, and aspects are also disclosed and contemplated by the present disclosure.

Additional embodiments of the disclosure are described below in reference to the appended claims, which may serve as an additional summary of the disclosure.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features. No single feature is solely responsible for its desirable attributes or is essential to practicing the disclosure herein described.

Bridges and interposers are useful for connecting dies (e.g., processor dies and/or memory dies, variety of chiplets, etc.) in a semiconductor package. However, costs associated with assembling the semiconductor package can be high, particularly when computational complexity increases. Some embodiments disclosed herein nevertheless accomplish cost effective, high yield, and/or time efficient implementations of semiconductor packaging by migrating or moving certain layers of processor dies to under-utilized spaces within other dies or substrates, e.g., interposers.

Interposers can be very useful for connecting dies in certain high performance computing applications (e.g., 2.5D applications with graphical processing units (GPUs) and high bandwidth memories (HBMs) connected by interposers, stitching two or more compute chips to form one large compute chip or stitching two or more chiplets (including die stacks) with same or different functionalities). However, the implementation of these interposers may incur significant cost and/or waste due to the underutilization of available real estate. For example, an interposer may need to provide high-density conductors (e.g., high-density wires or metal traces for connecting processor dies or multiple layers metal traces to provide high speed low resistance connections at fine pitches) only in a small area while remaining area that includes through-substrate-vias (TSVs) is relatively empty, not as densely wired or wired only to provide connections at broader pitches. For example, only smaller area of the interposer includes four to six metal layers at finer pitch connections, while rest of the remaining large area of the interposer may need or include only one to two metal layers. But since the wiring fabrication is a wafer level process, the larger portion would also need to be fabricated with four to six metal layers to match the smaller areas of high density wiring and the wiring in the remaining large area of the interposer remains underutilized. As such, less than 10%-30% of the interposer area may be used, especially for larger interposers (e.g., interposers with area exceeding 30×30 mm²). With the cost of the wafer significantly increasing with each additional wiring layers, such wiring or real estate underutilization may need to be addressed.

Although silicon bridges may be used to reduce the interposer area while providing high density metal wiring exclusively where they are needed and consequently reduce the cost waste, embedding bridges within a substrate (e.g., organic substrate like printed circuit board (PCB)) or fan-out configurations (e.g., wafer level or panel level packaging) may add process complexity to an assembly process, especially when required interposer or package footprint increases. As such, cost associated with a semiconductor package that includes bridges may still increase. Moreover, packaging and manufacturing challenges of such thin and large fanout configurations (e.g., coefficient of thermal expansion (CTE) differentials, minimal warpage, novel materials, thermal budget, etc.) may introduce reliability challenges. Additionally, the advanced manufacturing processes (e.g. advanced process nodes) used for high-end processor dies, such as GPUs, central processing units (CPUs), Neural processing units (NPU), Tensor processing units (TPU), field programmable gate arrays (FPGAs), and application specific integrated circuits (ASICs), etc. that are attached to such interposers may further escalate design and fabrication cost. For example, the intricate designs and fabrication steps used for processor dies that contain trillions of transistors and numerous metal layers may result in an exponential cost increase when a new computing node (e.g., a GPU die) is integrated effectively increasing the overall package cost. Such high processor dies (or chiplets) with trillions of transistors fabricated using the advanced process nodes typically require large number of metal layers (e.g., more than 10 to 20 metal layers) to manufacture a working chip. Each metallization layer being processed at such high-end manufacturing line may add significant cost.

To address at least a portion of the aforementioned problems, some embodiments herein transfer, move, or migrate several top most thick metallization layers or global interconnection layers (e.g., global input/output (I/O) layers) from processor dies, such as GPU dies, CPU dies, neural networking processing unit (NPU) dies, and tensor processing unit (TPU) dies, to under-utilized (e.g., unused, unoccupied, or less used) spaces within an interposer of a semiconductor package. For clarity, as used herein, the global interconnection layers are not physically transferred, moved, or migrated from the processor die(s) to the interposer. Rather, in the embodiments disclosed herein, global interconnection layers that would otherwise be formed on the processor die(s) in conventional devices are instead formed in the interposer. By moving the global interconnection layers from one or more processor dies (or chiplets) to the interposer, cost associated with the semiconductor package can be advantageously reduced. For example, by relocating one or more global I/O layers from a GPU die to an interposer, the number of steps used for fabricating the GPU die is reduced (e.g. global layers are not fabricated as a part of GPU wafer fabrication), which can lead to considerable cost savings especially when the GPU die is fabricated using advanced process (e.g., a five nanometer (nm) process) in a high end or expensive fab. Further, yield associated with fabricating the GPU die may increase (due to reduced wiring layers) and time associated with fabricating the GPU die may decrease due to the reduction of steps for fabricating the GPU die. Additionally, cost associated with the interposer may not increase because of moving the one or more global I/O layers from the GPU die to the relatively empty spaces of the interposer, which may be fabricated using less advanced process and would otherwise be fabricated and not used or under used. More specifically, cost reduction associated with passive interposers (e.g., interposers without active circuitry and only including wiring layers) may be more significant compared with cost reduction associated with active interposers. It should be noted cost reduction can still be obtained with active interposers because active interposers can be manufactured with less advanced process nodes compared with the manufacturing of processor dies. This is because, compared with processor dies, active interposers may have significantly fewer compute intensive circuits (e.g., I/O interface circuits, caches, fuse, or the like).

### Example Conventional Bonded Structure

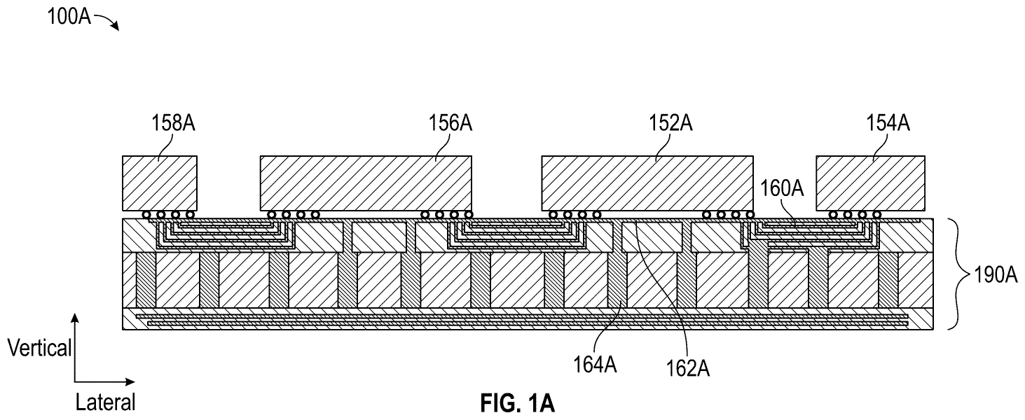

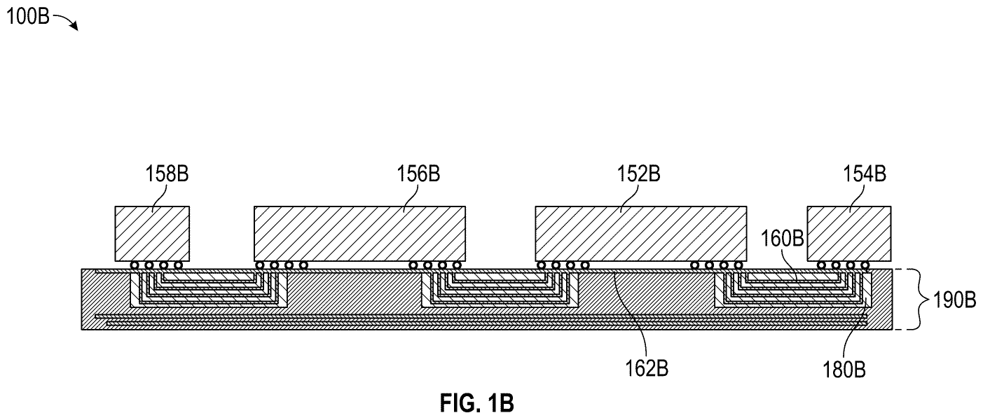

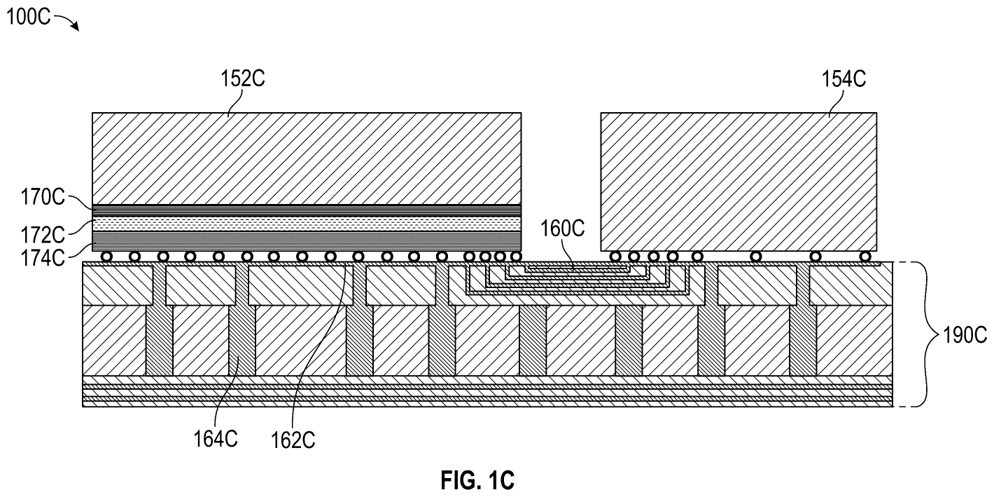

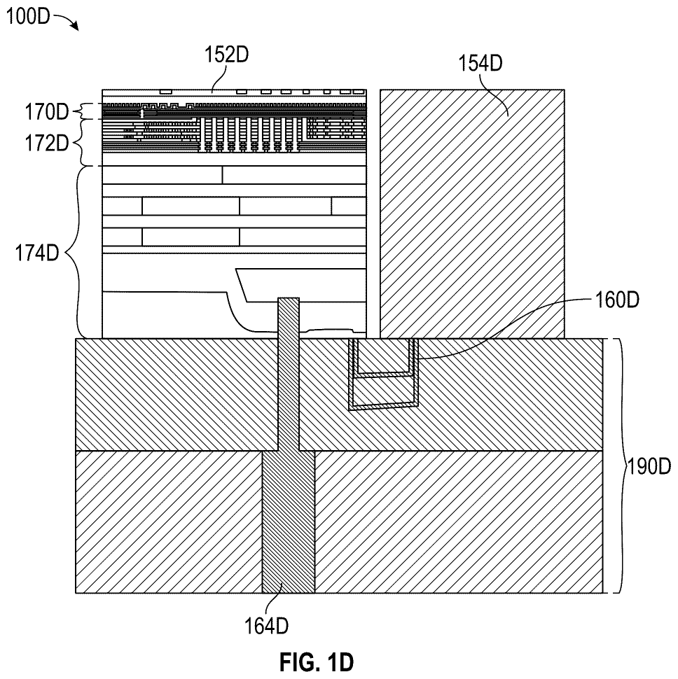

FIG. 1A illustrates a side schematic sectional view of a conventional bonded structure 100A that includes a memory unit 158A, a GPU die 156A, a GPU die 152A, conductors 160A, a memory unit 154A, and an interposer 190A that includes vias 164A and conductors 162A. It should be noted that the GPU die 156A and/or the GPU die 152A can be replaced by other processor die(s) such as CPU (central processing unit) dies, TPU (tensor processing unit) dies, NPU (neural networking processing unit) or other dies or chiplets with different functionalities. As shown in FIG. 1A, the memory unit 158A, the GPU die 156A, the GPU die 152A, and the memory unit 154A are disposed on the interposer 190A. The interposer 190A may facilitate communication between the memory unit 158A, the GPU die 156A, the GPU die 152A, the memory unit 154A, and other components (e.g., a substrate that is not shown) of the bonded structure 100A through the conductors 160A and the conductors 162A. For example, the GPU die 152A may communicate with the memory unit 154A through the conductors 160A. The interposer 190A may utilize the vias 164A and the conductors 162A to facilitate power provision or signal transmission associated with the interposer 190A and the substrate. The conductors 160A may be inter-chip high density connections or traces embedded in several metal layers (e.g., above four layers), where a pitch associated with the traces may be about 30 micrometer (μm) to 60 μm. The conductors 162A may be low density connections or traces embedded in one or two metal layers for routing signals associated with the GPU die 152A, where a pitch associated with the traces may be between 50 to 100 μm or above. Although not readily observed from FIG. 1A, a length along the lateral direction of the conductors 162A under the GPU die 152A (or the distance between two neighboring conductors 160A) may be between 15 to 100 millimeters (mm) (e.g., 60 mm) and a length along the lateral direction of the conductors 160A may be between 3 μm to 20 millimeters (mm). A lateral length of the shortest of the metal traces in conductors 162A may be 50 μm to 200 μm and a lateral length of the longest of the metal traces in conductors 162A may be 15 mm to 100 mm.

FIG. 1A shows that spaces within the interposer 190A are under-utilized, with only a small portion of the interposer 190A occupied by high-density interconnections (e.g., the conductors 160A), while the majority spaces (e.g., the portions that accommodate the conductors 162A) of the interposer 190A remain relatively empty or under-utilized. Although conductors 162A shown in FIG. 1A depicts only one metal layer, it is understood that conductors 162A may also have same number of layers in conductors 160A, but may be under utilized (e.g., less densely wired) as compared to conductors 160A. As such, the bonded structure 100A exemplifies the inefficiencies in current interposer implementations.

FIG. 1B illustrates a side schematic sectional view of a conventional bonded structure 100B that includes a memory unit 158B, a GPU die 156B, a GPU die 152B, conductors 160B, a memory unit 154B, interconnect bridges 180B, and a substrate 190B. As shown in FIG. 1B, the interconnect bridges 180B may include conductors 160B. Conductors 162B may be routed on the substrate 190B. Unless otherwise noted, components of FIG. 1B can be structurally and functionally the same as or generally similar to like-numbered components of FIG. 1A. For example, the conductors 160B may be inter-chip high density connections or traces for facilitating communication between the GPU die 152B and the memory unit 154B. The conductors 162B may be low density connections or traces embedded in one or two metal layers for routing signals associated with the GPU die 152B and power/ground lines.

As shown in FIG. 1B, the interconnect bridges 180B may provide high-density interconnections between multiple semiconductor dies, such as the GPU die 152B and the memory unit 154B. As such, compared with the bonded structure 100A, the interconnect bridges 180B (e.g. silicon bridge) may reduce interposer area used by the bonded structure 100B through embedding the interconnect bridges 180B within the substrate 190B to facilitate electrical connections among the memory unit 158B, the GPU die 156B, the GPU die 152B, and the memory unit 154B. The substrate may be a conventional build up package substrate, or a fanout wafer level substrate. However, employing the bonded structure 100B may add complexity to an assembly process and increases the overall cost due to the integration of the interconnect bridges 180B. Further, similar to the bonded structure 100A, the bonded structure 100B illustrates utilization of high-density interconnections in specific areas (e.g., areas within the interconnect bridges 180B), while a significant area of the substrate 190B remains underutilized and uses only limited number of wiring layers. For example, if the silicon bridge has four to six metal layers (i.e. conductors 160B) with the thickness of each layer between 500 um-1000 um, the conductors 162B may comprise only one to two metal layers of similar thickness, but formed as a part of cheaper substrate manufacturing process, As such, the bonded structure 100B exemplifies the inefficiencies and assembly challenges in current semiconductor packages. It should be noted that the silicon bridge may have any number of layers (e.g., layers associated with the conductors 160B and/or the conductors 162B) other than four to six metal layers.

FIG. 1C illustrates a side schematic sectional view of a portion of a conventional bonded structure 100C that includes a GPU die 152C, a memory unit 154C (e.g. HBM), and an interposer 190C that includes conductors 160C and vias 164C. Unless otherwise noted, components of FIG. 1C can be structurally and functionally the same as or generally similar to like-numbered components of FIG. 1A. As shown in FIG. 1C, the GPU die 152C includes local layers 170C, intermediate layers 172C, and global layers 174C. The local layers 170C and/or the intermediate layers 172C can be formed using low-k dielectric materials or extremely low-k (ELK) dielectric materials. The global layers 174C may comprise materials such as silicon oxide, silicon nitride, silicon oxynitride, silicon carbonitride, tetraethyl orthosilicate (TEOS) or other suitable inorganic material.

Global interconnects or wiring layers are the topmost metallization layers of the chip and make electrical connections between different blocks of the circuit and are thus typically thick, long, and widely separated. The global layers 174C may be used for facilitating global input/output (I/O) connections, power and ground lines across the processor die. More specifically, the global layers 174C can be used to connect various processor cores (e.g. logic core blocks not shown in FIG. 1C), cache, controller blocks (e.g., cache controller, HBM controller logic, etc.), fuses, analog circuit blocks, reference bias circuitry, IO interfaces, etc. of the GPU die 152C. For example, the global layers 174C can include conductors (e.g., conductive traces) used for power lines or connecting a first processor core of the GPU die 152C and a second processor core of the GPU die 152C. The intermediate layers 172C can be used for facilitating electrical connections within the GPU die 152C, such as between various blocks or regions of processor cores of the GPU die 152C. For example, the intermediate layers 172C can include conductors (e.g., conductive traces) used for connecting a first block of a processor core of the GPU die 152C to a second block of the processor core of the GPU die 152C. In some embodiments, the intermediate layers 172C can include conductors (e.g., conductive traces) used for connecting a first block of a processor core of the GPU die 152C to a first memory block (e.g. L1, L2, L3, instruction cache, etc.) of the GPU die 152C. In some embodiments, local interconnects or wiring layers are closest to the transistors and electrically connect the components that are themselves very small and closely packed together; hence are ultra thin and short in length. The local layers 170C can be used for facilitating electrical connections within the GPU die 152C, such as between various transistors of the GPU die 152C, between standard cells, etc. For example, the local layers 170C can include conductors (e.g., conductive traces) used to form the transistor circuit and for connecting a first transistor in a block of a processor core of the GPU die 152C to a second transistor in the block of the processor core of the GPU die 152C, conductors (e.g., conductive traces) used to build standard cell libraries, and/or the like. In some examples, traces in the global layers 174C may be thicker than traces in the intermediate layers 172C and local layers 170C. In some examples, the local layer thickness is below 100 nm, intermediate layer thickness is below 500 nm and global layer thickness is between 0.5-5 um. In some examples, the global layer thickness can be between 0.5 μm to 1 μm, 0.6 μm to 1.5 μm, 0.7 to 3.0 μm, or any range of values therebetween. In some examples, intermediate layer thickness can be 0.1 μm to 0.3 μm, 0.2 μm-0.5 μm, or any range of values therebetween. In some examples, local layer thickness can be less than 100 nm, less than 50 nm, less than 40 nm, less than 20 nm, or less than other length.

FIG. 1D illustrates a side schematic sectional view of a portion of a conventional bonded structure 100D that includes a GPU die 152D, a memory unit 154D (e.g. HBM), and an interposer 190D that includes conductors 160D and vias 164D. Unless otherwise noted, components of FIG. 1D can be structurally and functionally the same as or generally similar to like-numbered components of FIG. 1C.

As shown in FIG. 1D, the GPU die 152D includes local layers 170D that are extremely thin and dense, comparatively thicker intermediate layers 172D, and significantly thicker global layers 174D. The local layers 170D may include layers (e.g., four to eight copper (Cu) layers) for facilitating electrical connections within the GPU die 152D. The local layers 170D can include conductors (e.g., conductive traces) to form transistors, used for connecting a first transistor in a block of a processor core of the GPU die 152D to a second transistor in the block of the processor core of the GPU die 152D, conductors (e.g., conductive traces) used to build standard cell libraries, and/or the like. The intermediate layers 172D may include layers for facilitating electrical connections between different blocks or regions of the processor cores within the GPU die 152D. For example, the intermediate layers 172D can include conductors (e.g., conductive traces) used for connecting a first block (e.g., circuit block, functional block, etc.) of a processor core of the GPU die 152D to a second block of the processor core of the GPU die 152D. The global layers 174D may include global input/output (I/O) layers (e.g., one or more Cu layers and aluminum (Al) layers) for facilitating global connections across the GPU die 152D, such as facilitating connections for input/output interfaces, power distribution, ground lines, test pads, etc.

Similar to the bonded structure 100A, the conventional bonded structure 100C or 100D shows that spaces within the interposer 190C or 190D are under-utilized, with only a small portion of the interposer 190C or 190D occupied by high-density interconnections (e.g., the conductors 160C or 160D), while the majority spaces (e.g., the portions that accommodate the vias 164C and the conductors 162C that are under the GPU die 152C, or the portions that accommodate the vias 164D) of the interposer 190C or 190D remain relatively empty or lower density wiring. Although FIG. 1C (or 1D) depicts only one via layer under the GPU die 152C (or 152D), it is understood that this area of the interposer 190C (or 190D) under the shadow of GPU die 152C (or 152D) can also have same number of layers in conductors 160C (or 160D), but may be under-utilized (e.g. less densely wired) as compared to conductors 160C (or 160D). As such, the bonded structure 100C or 100D exemplifies the inefficiencies in current interposer implementations.

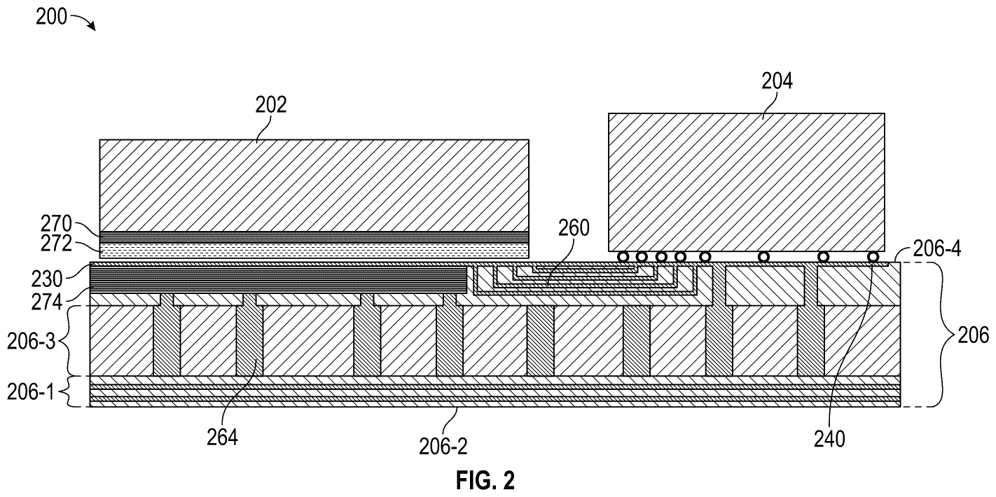

As noted above, some implementations disclosed herein (e.g., the implementations that will be discussed with reference to FIG. 2) can reduce cost associated with a semiconductor package by moving the global layers (e.g., the global layers 174C) from processor dies (e.g., the GPU die 152C) to under-utilized (e.g., unused, unoccupied, less-dense or less used) spaces within an interposer (e.g., the interposer 190C). By moving one or more global layers from a processor die to an interposer, number of steps used for fabricating the processor die is reduced, which can lead to considerable cost savings especially when the processor die is fabricated using advanced process (e.g., a two nanometer (nm) process). Further, yield associated with fabricating the processor die may increase and time associated with fabricating the processor die (in a high end fab) may decrease due to the reduction of steps for fabricating the processor die. In contrast, cost associated with the interposer may not increase because an interposer may already have four to six metal layers for routing the conductors 160C.

### Example Bonded Structure

FIG. 2 illustrates a side schematic sectional view of a bonded structure 200 including an interposer according to some embodiments. As shown in FIG. 2, the bonded structure 200 includes a processor die 202, a semiconductor die 204, conductors 260, and an interposer 206. The processor die 202 includes local layers 270 and intermediate layers 272. The interposer 206 includes vias 264, conductors 260, and global layers 274. The processor die 202 can be bonded to the interposer 206 using a bonding 230. The semiconductor die 204 can be bonded to the interposer 206 using a bonding 240. In some embodiments, the global layers 274 are transferred from the processor die 202 (e.g., a GPU die) to under-utilized (e.g., unused, unoccupied, or less used) spaces within the interposer 206.

The interposer 206 can comprise one or more conductive layers and materials for facilitating lateral and/or vertical electrical communication between various components of the bonded structure 200. For example, the interposer 206 can include the conductors 260 to facilitate lateral communication between the processor die 202 and the semiconductor die 204. In some examples, the conductors 260 may be inter-chip high density connections or traces embedded in several metal layers of the interposer 206. A pitch associated with the traces may be about 30 μm to 60 μm. As another example, the interposer 206 can include the vias 264 (e.g., vertical electrical connections, through silicon vias, etc.) for facilitating vertical communication associated with the interposer 206 (e.g., communication among various layers of the interposer 206, communication between the interposer 206 and other components of the bonded structure 200, communication between topside and bottom side of the interposer or communication between layers and/or components near the topside of the interposers and layers and/or components near the bottom side of the interposer, etc.). In some implementations, the vias 264 can be through-substrate vias (TSVs). Although not shown in FIG. 2, the interposer 206 can further include one or more dielectric layers that surround the one or more conductive layers to provide electrical insulation and structural support. In some other embodiments, the interposer can be embedded within dielectric material (e.g. organic or inorganic material). The interposer 206 (and/or the surrounding dielectric material) can additionally and/or optionally include one or more redistribution layers (RDLs) (not shown).

The processor die 202 can be a GPU die, CPU die, a TPU (tensor processing unit) die, a NPU (neural networking processing unit) die, ASIC die, FPGA die and/or any combination thereof. The semiconductor die 204 can be a GPU die, CPU die, a TPU, a NPU die, ASIC die, FPGA die or can include a memory die. In some examples, the semiconductor dies 204 may include a stack dies. In some examples, the processor die 202 may have one or more dies stacked it. In some examples, the semiconductor dies 204 may include a stack of memory dies that form a memory unit. The semiconductor die 204 may be bonded to the interposer 206 using the bonding 240. In some examples, the bonding 240 may be a hybrid bonding (e.g., using ZIBOND® or DBI® hybrid bonding technique). In these examples, a hybrid bonding pitch may range from 0.2 μm to 5 μm, such as from 0.2 μm to 0.5 μm, 02 μm to 1.0 μm, 0.3 μm to 3.0 μm, 0.5 μm to 5 μm, or any range of values therebetween. In other examples, the semiconductor die 204 may be thermally compressed or flip chipped to attach to the interposer 206.

As shown in FIG. 2, the processor die 202 includes the local layers 270 and the intermediate layers 272. In some examples, the intermediate layers 272 can be used for facilitating electrical connections within the processor die 202, such as between various blocks or regions of processor cores (not shown in FIG. 2) of the processor die 202. For example, the intermediate layers 272 can include conductors (e.g., conductive traces) used for connecting a first block of a processor core of the processor die 202 to a second block of the processor core of the processor die 202. In some examples, the intermediate layers 272 can include conductors (e.g., conductive traces) used for connecting a circuit or a functional block of the processor die 202 to another circuit or a functional block of the processor die 202 that is connected to the conductors 260 of the interposer 206. In some examples, the intermediate layers 272 can include conductors (e.g., conductive traces) used for connecting a circuit or a functional block of the processor die 202 to the conductors 260 of the interposer 206. In some examples, some portion of the intermediate layers 272 can be electrically connected to the conductors 260 of the interposer 206 using direct hybrid bonds. In some examples, at least some portions of the intermediate layers 272 can be electrically connected to the conductors 260 of the interposer 206 through the bonding 230 (e.g., a bonding layer) In some examples, the local layers 270 can be used for facilitating electrical connections within the processor die 202, such as between various transistors of the processor die 202. For example, the local layers 270 can include conductors (e.g., conductive traces) used for connecting a first transistor in a block of a processor core of the processor die 202 to a second transistor in the block of the processor core of the processor die 202.

In contrast to the global layers 174C that are disposed within the GPU die 152C as depicted in FIG. 1C, the global layers 274 of the processor die 202 are disposed within the interposer 206. In some examples, the global layers 274 can include conductors (e.g., conductive traces) used for connecting a first processor core of the processor die 202 and a second processor core of the processor die 202. In some embodiments, the global layers 274 can include conductors (e.g., conductive traces) used for connecting a first processor core of the processor die 202 and first memory block (e.g. L1, L2, L3 cache) of the processor die 202. In some embodiments, the global layers 274 can include conductors (e.g., conductive traces) used for connecting a first memory block of the processor die 202 (e.g. L1, L2 or L3 cache) and second memory block of the processor die 202. In some embodiments, the global layers 274 can include conductors (e.g., conductive traces) used for connecting a first memory block of the processor die 202 (e.g., L1, L2 or L3 cache not shown in FIG. 2) and memory controller block of the processor die 202. In some embodiments, the global layers 274 can include conductors (e.g., conductive traces) used for connecting a first block of block of the processor die 202 comprising at least one of processor core (i.e. logic core), memory/cache (e.g. L1, L2 or L3 cache), memory controller, analog circuit block, etc. to another block of the processor die 202 comprising at least one of input/output (I/O) interfaces (HBM interface including HBM control logic, I/O block, I/O control logic, fuse, PCIe/NV link interface, general purpose IOs (GPIO), etc.). In some embodiments, the local layers 270, the intermediate layers 272, and the global layers 274 can facilitate complete functionality associated with the processor die 202. As used herein, complete functionality can mean that the processor die 202 provides or supports all functions that the processor die 202 is designed for. Complete functionality associated with the processor die 202 may be achieved by establishing all electrical connections through the local layers 270, the intermediate layers 272, and the global layers 274 to allow communications between transistors, processor cores, memory blocks, and external interfaces associated with the processor die 202. Without the global layers 274, the processor die 202 may not provide complete functionality (but may provide partial functionality) because, for example, processor cores of the processor die 202 are not electrically connected due to the absence of the global layers 274. In this situation, the intermediate layers 272 and the local layers 270 may facilitate partial functionality associated with the processor die 202, but the intermediate layers 272 and local layers 270 may not provide complete functionality associated with the processor die 202.

In some examples, a pitch of a trace in the local layers 270 and the intermediate layers 272 can be smaller than a pitch of a trace in the global layers 274. Further, a trace in the global layers 274 may be thicker than a trace in the local layers 270 and the intermediate layers 272. In some embodiments, the local layers 270 and/or the intermediate layers 272 can be formed using low-k inorganic dielectric materials or extremely low-k (ELK) inorganic dielectric materials. These materials may advantageously help reduce parasitic capacitance within densely packaged chips or devices, thereby improving signal speed and reducing power consumption and making the bonded structure 200 suitable for high-speed and/or high performance semiconductor applications. In some embodiments, the global layers 274 may be formed using materials such as silicon oxide, silicon nitride, or tetraethyl orthosilicate (TEOS). These materials may be utilized because of their insulating properties and mechanical stability, which can advantageously maintain the integrity of global interconnections (e.g., interconnections that connect different processor cores of the processor die 202) embedded in the global layers 274. As such, the bonded structure 200 can provide reliable performance for high-density and high-complexity semiconductor packages.

By relocating the global layers 274 from within the processor die 202 to the interposer 206, the bonded structure 200 may advantageously reduce the number of fabrication steps required for the processor die 202, thereby lowering costs and improving yield associated with manufacturing of the processor die 202 that may be fabricated using advanced process (e.g., a 5 nanometer (nm) 3 nm, 2 nm processes, sub-nm processes, Gate all around (GAA), nanowire processes, nano-sheet processes, etc.). Further, by moving the global layers 274 away from the processor die 202, the processor die 202 may be bonded to the interposer 206 using the bonding 230 based on hybrid bonding (e.g., using ZIBOND® or DBI® hybrid bonding technique) because of the fine pitch (e.g., a pitch associated with the intermediate layers 272 being smaller than a pitch associated with the global layers 274) of the processor die 202. In some examples, the fine pitch may be less than 30 μm, less than 10 μm, or less than 5 μm, or the like.

Additionally, the bonded structure 200 allows for more efficient use of the area within the interposer 206 (e.g., compared with the interposer 190C), as the global layers 274 occupy previously underutilized spaces (e.g., areas where the conductors 260 are not routed) within the interposer 206. This may reduce the overall cost associated with assembling the bonded structure 200 and/or simplify the assembly process by avoiding the complexity associated with embedding bridges (e.g., the interconnect bridges 180B) or other high-density interconnections within a substrate. As such, by transferring global layers 274 from the processor die 202 to the interposer 206, the bonded structure 200 addresses the inefficiencies and cost challenges associated with conventional bonded structures 100A, 100B, and 100C by leveraging the underutilized spaces within the interposer 206 to achieve more cost-effective and efficient semiconductor package designs.

In some embodiments, the bottom silicon portion (e.g., a region 206-3 and/or a region 206-1) of the interposer 206 can be completely removed (e.g. by polishing, grinding, etching,etc.) and only conductors 260 and global layers 274 remain, which are exposed to form the contacts on the bottom side to attach the interposer 206 to a bottom substrate (not shown in FIG. 2) without the need of through substrate connections (e.g., the vias 264). Advantageously, removing the bottom silicon portion of interposer 206 may reduce thickness of the bonded structure 200, thereby beneficial for reducing overall thickness of a semiconductor package and making the bonded structure 200 suitable for use in applications where packaging space is limited or where thinner packages are needed. In some embodiments, the bottom silicon portion of interposer 206 can be attached to a substrate (e.g., organic substrate such as PCB) to facilitate mounting the bonded structure 200 to a system motherboard (not shown in FIG. 2). Additionally, heat sink(s) or cooling component(s) may be disposed on the bottom silicon portion or the other side (e.g., the side of the interposer where the processor die 202 is disposed) of the interposer 206, thereby improving heat dissipation and enhancing thermal performance and reliability of the bonded structure 200.

In some embodiments, silicon capacitors (e.g. deep trench capacitors, massive passives, etc.) are formed or manufactured inside the interposer 206 or attached to the bottom of the interposer 206 (or between the interposer 206 and the processor die 202). For example, one or more capacitors may be disposed in a region 206-1 of the interposer 206, on a bottom surface 206-2 of the interposer 206, and/or in other region of the interposer 206. In some embodiments, a capacitor wafer can be attached to the top or bottom of the interposer 206 for smooth power delivery across the die(s). When the capacitor wafer is bonded to the top of the interposer 206, the capacitor wafer can bet sandwiched between the global layers 274 and the intermediate layers 272.

As noted above, one or more redistribution layers (RDLs) (not shown in FIG. 2) can be included in the interposer 206. In some embodiments, the one or more redistribution layers (RDLs) can be disposed near a top side 206-4 of the interposer 206 or other regions of the interposer 206. The one or more RDLs can be used to connect processor cores (e.g., a first processor core of the processor die 202 and a second processor core of the processor die 202) or circuit blocks (e.g., a cache of the processor die 202, controller, I/O interfaces, etc.) of the processor die 202. The one or more RDLs can also be used to redistribute I/O connections associated with the interposer 206, thereby allowing electrical pathways to be efficiently routed between the interposer 206, the processor die 202, and/or the semiconductor die 204. In some embodiments, the one or more RDLs within the interposer 206 can be composed of alternating metal and dielectric layers. The metal layers can be used to create electrical connections, while the dielectric layers can provide insulation and mechanical support. The metal layers can be made of materials such as copper or aluminum to provide adequate conductivity. The dielectric layers can be made of inorganic dielectric materials such as silicon dioxide (SiO₂), silicon nitride (Si₃N₄), or other low-k dielectric materials to reduce or minimize parasitic capacitance.

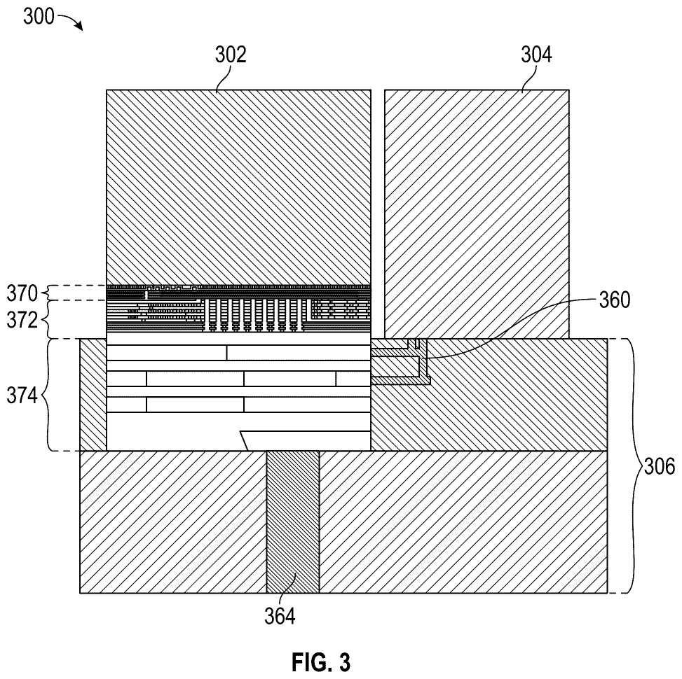

FIG. 3 illustrates a side schematic sectional view of a bonded structure 300 including layers in a processor die 302 according to some embodiments. The bonded structure 300 includes the processor die 302, a semiconductor die 304, conductors 360, and an interposer 306. The processor die 302 include local layers 370 and intermediate layers 372. The interposer 306 includes conductors 360, vias 364, and global layers 374. Unless otherwise noted, components of FIG. 3 can be structurally and functionally the same as or generally similar to like-numbered components of FIG. 2.

In some embodiments, the local layers 370 may include one or more layers (e.g., copper (Cu) layers) that can be used for facilitating electrical connections within the processor die 302. The local layers 370 can include conductors (e.g., conductive traces) used for connecting a first transistor in a block of a processor core of the processor die 302 to a second transistor in the block of the processor core of the processor die 302, conductors (e.g., conductive traces) used to build standard cell libraries, and/or the like. The local layers 370 can advantageously handle high-density connections with fine pitches, thereby accomplishing efficient data transfer and signal integrity within the die processor die 302.

In some embodiments, the intermediate layers 372 may include layers for facilitating electrical connections between different blocks or regions of the processor cores within the processor die 302. For example, the intermediate layers 372 can include conductors (e.g., conductive traces) used for connecting a first block of a processor core of the processor die 302 to a second block of the processor core of the processor die 302. Compared with the local layers 370, the intermediate layers 372 can provide routing paths for signals that need to travel longer distances within the processor die 302. In some embodiments, the intermediate layers 372 can be used to balance wiring density and performance within the processor die 302, thereby ensuring reliable communication while minimizing parasitic effects.

In contrast to the implementation of FIG. 1D where the global layers 174D are disposed within the GPU die 152D, the global layers 374 of the processor die 302 are disposed within the interposer 306 to achieve the technical benefits (e.g., lowering cost and improving yield associated with manufacturing the processor die 302, enabling hybrid bonding between the processor die 302 and the interposer 306, and increasing utilization of spaces within the interposer 306) described with reference to FIG. 2. In some embodiments, the global layers 374 may include global input/output (I/O) layers (e.g., one or more Cu layers and aluminum (Al) layers) for facilitating global connections across the processor die 302, such as facilitating connections for input/output interfaces, power distribution, and ground lines. The global layers 374 can also electrically connect a first processor core of the processor die 302 and a second processor core of the processor die 302. The global layers 374 can optionally connect the processor die 302 to external components, such as the semiconductor die 304 and the interposer 306, enabling communication between the processor die 302 and other parts of a semiconductor package.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

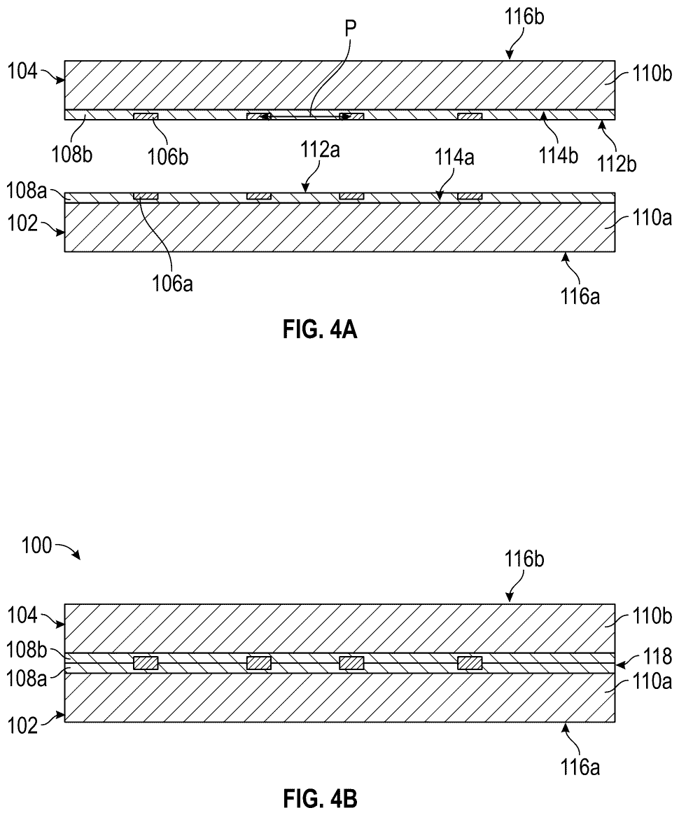

FIGS. 4A and 4B schematically illustrate cross-sectional side views of first and second elements 102, 104 prior to and after, respectively, a process for forming a directly bonded structure, and more particularly a hybrid bonded structure, according to some embodiments. In FIG. 4B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Årms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 4A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm. For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A; B; C; A and B; A and C; B and C; and A, B, and C. Conjunctive language such as the phrase “at least one of X, Y and Z,” unless specifically stated otherwise, is understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

1. A structure comprising:
a processor die comprising a first processor core and a first circuit block;
a semiconductor die; and
a connecting element hybrid bonded to the processor die and electrically connecting at least the processor die and the semiconductor die, the connecting element comprising a first plurality of conductors electrically connecting the first processor core and the first circuit block,
wherein the first processor core and the first circuit block communicate with each other through the first plurality of conductors.

2. The structure of claim 1, wherein the first circuit block comprises a second processor core or a first cache.

3. The structure of claim 1, wherein the processor die does not include a global redistribution layer (RDL) that is used to connect processor cores or circuit blocks of the processor die.

4. The structure of claim 1, wherein the processor die comprises a second plurality of conductors electrically connecting at least a first block of the first processor core and a second block of the first processor core.

5. The structure of claim 4, wherein the processor die comprises a third plurality of conductors electrically connecting at least a first transistor of the first block of the first processor core and a second transistor of the first block of the first processor core.

6. The structure of claim 5, wherein the second plurality of conductors and the third plurality of conductors facilitate partial functionality associated with the processor die, and wherein the first plurality of conductors, the second plurality of conductors, and the third plurality of conductors facilitate complete functionality associated with the processor die.

7. The structure of claim 4, wherein the processor die comprises one or more intermediate layers, wherein the second plurality of conductors are embedded in the one or more intermediate layers, and wherein a thickness of the one or more intermediate layers is less than 0.5 μm.

8. The structure of claim 5, wherein the processor die comprises one or more local layers, and wherein the third plurality of conductors are embedded in the one or more local layers.

9. (canceled)

10. (canceled)

11. The structure of claim 1, wherein the connecting element comprises one or more through substrate vias (TSVs).

12. (canceled)

13. (canceled)

14. (canceled)

15. (canceled)

16. (canceled)

17. (canceled)

18. (canceled)

19. The structure of claim 1, wherein the connecting element is an interposer, the interposer comprising one or more global redistribution layers (RDLs).

20. The structure of claim 19, wherein the connecting element comprises one or more capacitors embedded in the one or more global redistribution layers (RDLs).

21. (canceled)

22. (canceled)

23. (canceled)

24. A structure comprising:
a first processor die comprising a first processor core and a second processor core, the first processor die disposed above and hybrid bonded to an interposer; and
the interposer comprising a first plurality of conductors electrically connecting the first processor core and the second processor core,
wherein the first processor core and the second processor core communicate with each other through the first plurality of conductors.

25. The structure of claim 24, further comprising a substrate, wherein the interposer comprises one or more through substrate vias (TSVs) that electrically connect the interposer to the substrate.

26. (canceled)

27. A structure comprising:
an interposer having a global interconnect layer region;
a processor die comprising a plurality of processor cores and a memory cache, the processor die hybrid bonded to the interposer, the processor die comprising first interconnect layers and second interconnect layers; and
a semiconductor die bonded to the interposer and electrically connected to the processor die through the interposer,
wherein the global interconnect layer region of the interposer, the first interconnect layers of the processor die, and the second interconnect layers of the processor die facilitate complete functionality of the processor die.

28. The structure of claim 27, wherein a first processor core of the plurality of processor cores and a second processor core of the plurality of processor cores communicate with each other through the global interconnect layer region of the interposer.

29. The structure of claim 27, further comprising one or more capacitors, wherein the processor die and the semiconductor die are disposed on a first side of the interposer, and wherein the one or more capacitors are disposed on a second side of the interposer that is opposite to the first side of the interposer.

30. The structure of claim 27, wherein the second interconnect layers electrically connect at least a first block of a first processor core of the plurality of processor cores and a second block of the first processor core of the plurality of processor cores.

31. The structure of claim 30, wherein the first interconnect layers electrically connect at least a first transistor of the first block of the first processor core of the plurality of processor cores and second transistor of the first block of the first processor core of the plurality of processor cores.

32. The structure of claim 1, wherein the processor die comprises a second plurality of conductors electrically connecting at least a first block of the first processor core and a second block of the first processor core, wherein the second plurality of conductors are hybrid bonded to the first plurality of conductors.

32. The structure of claim 32, wherein a hybrid bonding pitch for hybrid bonding the first plurality of conductors and the second plurality of conductors is between 0.2 μm to 5 μm.
